(19) United States
(12) Patent Application Publication
(10) Pub. No.: US 2026/0327787 A1
(43) Pub. Date: Oct. 22, 2026

(54) NONCONFORMAL FILMS DEPOSITED WITHIN A RECESS USING ATOMIC LAYER DEPOSITION

(71) Applicant: Lam Research Corporation, Fremont, CA (US)

(72) Inventors: Ian John CURTIN, Portland, OR (US); Pulkit AGARWAL, Beaverton, OR (US); Wanki KIM, Portland, OR (US); Jennifer Leigh PETRAGLIA, Portland, OR (US)

(21) Appl. No.: 19/122,710

(22) PCT Filed: Nov. 7, 2023
(86) PCT No.: PCT/US2023/079015

§ 371 Date: Apr. 18, 2025

Related U.S. Application Data
(60) Provisional application No. 63/384,198, filed on Nov. 17, 2022.

(51) Int. Cl. C23C 16/04; C23C 16/56; H10P 14/60

(52) U.S. Cl. CPC C23C 16/045; C23C 16/56; H10P 14/6336; H10P 14/6339

(57) ABSTRACT

Examples are disclosed that relate to a method of depositing a film on a lower portion of a recessed feature on a substrate support using atomic layer deposition (ALD). One example provides a method comprising arranging a substrate comprising a recessed feature on a substrate support in an ALD processing chamber, the recessed feature comprising a recess wall extending into the substrate from an opening of the recessed feature in the substrate surface. The method further comprises supplying an inhibitor to the ALD processing chamber and forming a plasma comprising the inhibitor in the ALD processing chamber. This creates an inhibited recess wall surface adjacent the opening of the recessed feature. The method further comprises performing ALD to deposit a film on the recess wall that is thicker at a greater depth in the recessed feature than on the inhibited recess wall surface.

### BACKGROUND

Electronic device fabrication processes may involve many steps of material deposition, patterning, and removal to form integrated circuits on substrates. For example, atomic layer deposition (ALD) can be used to form a film on a substrate in a layer-by-layer manner using one or more deposition cycles. In an ALD cycle, a film precursor is adsorbed onto a surface of a substrate disposed in a processing chamber. Excess film precursor is purged from the processing chamber, and the adsorbed film precursor is chemically converted into a film on the substrate. For example, the adsorbed precursor can be oxidized to form an oxide film. A highly conformal film of a target thickness can be grown using one or more deposition cycles.

### SUMMARY

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter. Furthermore, the claimed subject matter is not limited to implementations that solve any or all disadvantages noted in any part of this disclosure.

Examples are disclosed that relate to forming films using atomic layer deposition (ALD). One example provides a method comprising arranging a substrate comprising a recessed feature on a substrate support in an ALD processing chamber. The recessed feature comprises a recess wall extending into the substrate from an opening of the recessed feature in the substrate surface. The recess wall comprises a first depth and a second depth. The first depth is closer to the substrate surface than the second depth. The method further comprises supplying an inhibitor to the processing chamber and forming a plasma comprising the inhibitor in the processing chamber to create an inhibited surface at the first depth. The method further comprises performing ALD to deposit a film that is thicker at the second depth first depth than at the first depth.

In some such examples, the film alternatively or additionally comprises one or more of silicon oxide, silicon oxynitride, silicon nitride, silicon carbide, or silicon oxycarbide.

In some such examples, the inhibitor alternatively or additionally comprises a fluorine-containing inhibitor.

In some such examples, the film alternatively or additionally comprises a metal film.

In some such examples, the inhibitor alternatively or additionally comprises a nitrogen-containing inhibitor.

In some such examples, the inhibitor alternatively or additionally comprises one or more of F₂, H₂, N₂, NF₃, CF₄, SF₆, HF, XeF₂, NH₃, an aminoalcohol, an amine, or a diamine.

In some such examples, the film alternatively or additionally comprises one or more of a metal oxide film or a metal oxide/silicon oxide laminate film.

In some such examples, the method alternatively or additionally further comprises removing the inhibitor from the substrate surface by a passivation cycle.

In some such examples, the recessed feature alternatively or additionally comprises an aspect ratio that is greater than or equal to 20:1, and less than or equal to 200:1.

In some such examples, the method alternatively or additionally further comprises performing ALD to deposit a conformal film on the substrate including within the recessed feature prior to supplying the inhibitor to the processing chamber.

In some such examples, the conformal film and the film that is thicker at the second depth comprise a same material.

In some such examples, the conformal film alternatively or additionally comprises a thickness of about 40 Angstroms to about 90 Angstroms.

In some such examples, the inhibitor and the film precursor are supplied to the ALD processing chamber simultaneously.

Another example provides a method comprising arranging a substrate comprising a recessed feature on a substrate support in an atomic layer deposition (ALD) processing chamber. The recessed feature comprises a recess wall extending into the substrate from an opening of the recessed feature. The recessed feature further comprises a first depth and a second depth, the first depth being closer to the opening than the second depth. The method further comprises performing ALD to deposit a first conformal film on the substrate including on the recess wall. The method further comprises supplying an inhibitor to the processing chamber and forming a plasma comprising the inhibitor in the processing chamber to create an inhibited surface within the recessed feature at the first depth. The method further comprises performing ALD to deposit a second film that is thicker at the second depth than at the first depth.

In some such examples, the first conformal film and the second film alternatively or additionally independently comprise silicon oxide, silicon oxynitride, silicon nitride, silicon carbide, or silicon oxycarbide.

In some such examples, the inhibitor alternatively or additionally comprises a fluorine-containing inhibitor.

In some such examples, at least one of the first conformal film and the second film alternatively or additionally comprises a metal film.

In some such examples, the inhibitor alternatively or additionally comprises a nitrogen-containing inhibitor.

Another example provides a structure formed on a substrate by atomic layer deposition (ALD), the structure comprising a recessed feature formed on the substrate. The recessed feature comprises a recess wall extending into the substrate from an opening of the recessed feature in a substrate surface. The recess wall comprises a first depth and a second depth. The first depth is closer to the opening than the second depth The structure further comprises a first conformal film disposed on the substrate surface and on the recess wall. The structure further comprises a second film disposed on the first conformal film at the second depth and not at the first depth such that an overall film thickness is thicker at the second depth than at the first depth.

In some such examples, the first conformal film and the second film independently comprise silicon oxide, silicon oxynitride, silicon nitride, silicon carbide, or silicon oxycarbide.

### BRIEF DESCRIPTION OF THE DRAWINGS

FIG. 1 shows a block diagram depicting an example ALD tool.

FIG. 2 shows a flow diagram depicting an example method of nonconformally depositing by ALD within a recessed feature.

FIGS. 3A-3C schematically show structures formed in an example process of nonconformally depositing a film on portions of a substrate within a recessed feature.

FIG. 4 shows a flow diagram depicting an example method of depositing a first conformal film on a substrate including a recessed feature, and nonconformally depositing a second film on portions of the substrate within the recessed feature.

FIGS. 5A-5D schematically show structures formed in an example process of depositing a first conformal film on a substrate including a recessed feature, and nonconformally depositing a second film on portions of the substrate located within the recessed feature.

FIGS. 6A-6D schematically show structures formed in an example process of depositing a first conformal film on a substrate including a recessed feature, and depositing a second distinct film having a laminate composition on portions of the substrate located within the recessed feature.

FIG. 7 shows a flow diagram of an example ALD cycle that omits an inhibitor.

FIG. 8 shows a flow diagram of an example ALD cycle that includes an inhibitor.

FIG. 9 shows a flow diagram of another example ALD cycle that includes an inhibitor.

FIG. 10 shows a flow diagram of an example method for performing inhibited ALD using a plurality of ALD cycles.

FIG. 11 shows a flow diagram of an example method for performing inhibited ALD using a plurality of ALD cycles and a passivation step.

FIG. 12 shows a flow diagram of another example method for performing inhibited ALD using a plurality of ALD cycles and a plurality of passivation steps.

FIG. 13 shows a flow diagram of another example method for performing inhibited ALD sing a plurality of ALD cycles and a plurality of passivation steps.

FIG. 14 shows a block diagram of an example computing system.

### DETAILED DESCRIPTION

The term “alkyl amine” may generally represent hydrocarbon compounds comprising a nitrogen with 1 to 3 alkyl substituents and 0 to 2 H substituents. Alkyl amines comprise primary, secondary, tertiary, and cyclic amines. Examples of alkyl amines include methylamine, dimethylamine, trimethylamine, and piperidine.

The term “aspect ratio” may generally represent a ratio between a depth of a recessed feature and an average width of the recessed feature.

The term “atomic layer deposition” (ALD) may generally represent a process in which a film is formed on a substrate in one or more individual layers by sequentially adsorbing a precursor conformally to the substrate and reacting the adsorbed precursor to form a film layer. Examples of ALD processes comprise plasma-enhanced ALD (PEALD), remote plasma-enhanced ALD (RPEALD) and thermal ALD (TALD). PEALD and TALD respectively utilize a plasma of a reactive gas and heat to facilitate a chemical conversion of a precursor adsorbed to a substrate to a film on the substrate. RPEALD uses a remote plasma located away from a substrate being processed to produce facilitate a chemical conversion of a precursor adsorbed to a substrate to a film on the substrate. The terms “growth” and “deposition”, and variants thereof, also may be used to refer to film formation.

The term “ALD cycle” may generally represent a sequence of processes used to form a layer of a film in an ALD process.

The term “ALD cycle comprising an inhibitor” may generally represent an ALD cycle that includes supplying of an inhibitor to a processing chamber during the cycle.

The term “ALD tool” may generally represent a machine comprising a processing chamber and other hardware configured to perform ALD processing.

The term “conformal film” may generally represent a film applied to a substrate using ALD that follows a contour of a substrate. In some examples, a conformal film may be formed by saturating a substrate surface with a film precursor in the absence of an inhibitor, and then chemically converting the film precursor to the conformal film.

The term “film precursor” may generally represent any material that can be supplied to a processing chamber to form an oxide film on a substrate disposed within the processing chamber. Examples of film precursors include silicon-containing precursors that can be used to form silicon-containing films such as silicon oxide, silicon oxynitride, and silicon oxycarbide films. Other examples of film precursors include metal-containing precursors for forming metal oxide films. Examples of such metal-containing precursors include aluminum-containing precursors, hafnium-containing precursors, titanium-containing precursors, tungsten-containing precursors, tin-containing precursors, and molybdenum-containing precursors, which respectively may be used to form aluminum oxide (Al₂O₃), hafnium oxide (HfOₓ), titanium oxide (TiOₓ), tungsten oxide (WOₓ), tin oxide (SnOₓ), and molybdenum oxide (MoOₓ) films.

The term “gas mixture” may generally represent a mixture of two or more gases in a processing chamber during an ALD process.

The term “inhibitor” may generally represent a compound that can be supplied to a processing chamber, that can be deposited nonconformally on a substrate surface, and that inhibits ALD growth of an oxide film. Example inhibitors include molecular hydrogen, nitrogen-containing inhibitors, fluorine-containing inhibitors, and carbon-containing inhibitors.

Examples of suitable nitrogen-containing inhibitors may include nitrogen (N₂), ammonia (NH₃), amines, diamines, aminoalcohols, or a combination of two or more thereof.

Examples of suitable fluorine-containing inhibitors may include F₂, NF₃, fluorocarbons such as CF₄ or C₂F₆, SF₆, HF, XeF₂, or a combination of two or more thereof.

Examples of suitable carbon-containing inhibitors may include thiols, diols, alkanes, alkenes, alkynes, cyclic hydrocarbons, aromatics, alcohols, aldehydes, esters, ethers, ketones, aldehydes, alkyl halides, alkyl amines, and alkyl diamines. In some examples, the carbon-containing inhibitor may comprise an alkane comprising a general formula CₙH₂ₙ₊₂ in which n=1 to 10. Examples of suitable alkanes may include methane, ethane, propane, butane, pentane, hexane, and substituted alkanes. Other examples of carbon-containing inhibitors may comprise an alkene, an alkyne, a cyclic hydrocarbon, an aromatic, an alcohol, a diol, an aldehyde, an ester, an ether, a ketone, an alkyl halide, an alkyl amine, or an alkyl diamine. In still other examples, the carbon-containing inhibitor may comprise a mixture of carbon-containing inhibitors. Examples of suitable alkenes (CₙH₂ₙ in which n=2 to 10, for an alkene with a single carbon-carbon double bond) may include ethene, propene, and butene. Examples of suitable alkynes (CₙH₂ₙ₋₂ in which n=2 to 10, for an alkyne with a single carbon-carbon triple bond) may include acetylene, propyne, and butyne. Examples of suitable cyclic hydrocarbons may include cyclobutane, cyclopentane and cyclohexane. Examples of suitable aromatics may include benzene, toluene, pyridine, and pyrimidine. Examples of suitable alcohols may include methanol, ethanol, and propanol. Examples of suitable diols may include ethylene glycol, propylene glycol, and hydroquinone. Examples of suitable aldehydes may include formaldehyde and acetaldehyde. Examples of suitable esters may include ethyl formate, methyl acetate, and ethyl acetate. Examples of suitable ethers may include diethyl ether, methyl phenyl ether, and aromatic ethers such as furan. Examples of suitable ketones may include acetone and methyl ethyl ketone. Examples of suitable alkyl halides may include ethyl fluoride, isopropyl bromide, and t-butyl chloride. Examples of suitable alkyl amines may include methylamine, dimethylamine, trimethylamine, and piperidine. Examples of suitable alkyl diamines may include ethylenediamine and 1,3-diaminopropane.

The term “oxidant” may generally represent a gas species containing oxygen available for reacting with a film precursor to form an oxide film. Examples of oxidants comprise molecular oxygen (O₂), water vapor (H₂O), hydrogen peroxide (H₂O₂), ozone (O₃), and nitrous oxide (N₂O).

The term “oxide film” may generally represent a film deposited on a substrate surface that comprises oxygen and an oxidized species. Examples of oxide films comprise films of doped or undoped silicon oxide (e.g., silicon oxide (SiO₂), silicon oxynitride (SiOₓN_{y}, 0≤x≤2, 0≤y≤1.33), silicon oxycarbide (SiCₓO_{2-y}, 0≤x≤1, y=2x)), and metal oxides, such as aluminum oxide (Al₂O₃) hafnium oxide (HfOₓ), titanium oxide (TiOₓ), tungsten oxide (WOₓ), tin oxide (SnOₓ), and molybdenum oxide (MoOₓ).

The term “plasma” may generally represent an ionized gas comprising gas-phase cations and free electrons.

The term “processing chamber” may generally represent an enclosure in which chemical and/or physical processes are performed on substrates. The pressure, temperature, gas flow rate, and atmospheric composition within a processing chamber may be controllable to perform chemical and/or physical processes. Controllable aspects of atmospheric composition include one or more of gas mixture or plasma conditions.

The term “recessed feature” may generally represent an opening in a substrate that extends below a substrate surface. The recessed feature comprises a recess wall extending into the substrate from the opening of the recessed feature in the substrate surface.

The term “silicon-containing precursor” may generally represent any material that can be supplied to a processing chamber in a gas phase to form a silicon-containing oxide film on the substrate. Example film precursors for forming silicon-containing films using PEALD may comprise materials having the general structure:

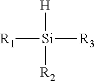

where R₁, R₂ and R₃ may be the same or different substituents, and may include silanes, siloxy groups, amines, halides, hydrogen, or organic groups, such as alkylamines, alkoxy, alkyl, alkenyl, alkynyl, and aromatic groups.

Example silicon-containing precursors include polysilanes (H₃Si—(SiH₂)ₙ—SiH₃), where n≥1, such as silane, disilane, trisilane, tetrasilane, and trisilylamine.

In some examples, the silicon-containing precursor is an alkoxysilane. Alkoxysilanes that may be used include the following:
Hₓ—Si—(OR)_{y}, where x=1-3, x+y=4 and each R is a substituted or unsubstituted alkyl, alkenyl, alkynyl or aromatic group; and
Hₓ(RO)_{y}, —Si—Si—(OR)_{y}Hₓ, is a substituted or unsubstituted alkyl, alkenyl, alkynyl or aromatic group.

Examples of silicon-containing precursors include tetraethyl orthosilicate (TEOS), tetramethoxysilane (TMOS), methylsilane, trimethylsilane (3MS), ethylsilane, butasilanes, pentasilanes, octasilanes, heptasilane, hexasilane, cyclobutasilane, cycloheptasilane, cyclohexasilane, cyclooctasilane, cyclopentasilane, 1,4-dioxa-2,3,5,6-tetrasilacyclohexane, diethoxymethylsilane (DEMS), diethoxysilane (DES), dimethoxymethylsilane, dimethoxysilane (DMOS), methyl-diethoxysilane (MDES), methyl-dimethoxysilane (MDMS), t-butoxydisilane, triethoxysilane (TES), and trimethoxysilane (TMS or TriMOS).

In some examples, the silicon-containing precursor may be a siloxane. Example siloxanes include octamethylcyclotetrasiloxane (OMCTS), octamethoxydodecasiloxane (OMODDS), tetramethylcyclotetrasiloxane (TMCTS), triethoxysiloxane (TRIES), and tetraoxymethylcyclotetrasiloxane (TOMCTS).

As noted above, in some examples, the silicon-containing precursor may be an aminosilane, such as bisdiethylaminosilane, diisopropylaminosilane, bis(t-butylamino) silane (BTBAS), di-sec-butylaminosilane, or tris(dimethylamino) silane (3DMAS). Aminosilane precursors may have the general formula: Hₓ—Si—(NR)_{y}, where x=1-3, x+y=4, and R is a substituted or unsubstituted alkyl, alkenyl, alkynyl or aromatic group or hydride group.

In some examples, a halogen-containing silane may be used such that the silane includes at least one hydrogen atom. Such a silane may have a chemical formula of SiXₐH_{y} where X is a halogen and y≥1. Dichlorosilane (H₂SiCl₂) may be used in some examples.

An example precursor for providing nitrogen for formation of a silicon oxynitride film is N₂O.

Example aluminum-containing precursors for forming aluminum oxide films (Al₂O₃) include aluminum halides (AlX₃), trimethylaluminum (Al(CH₃)₃), aluminum alkoxides such as aluminum ethoxide (Al(OC₂H₅)₃), alane trimethylamine (AlH₃·N(CH₃)₃), and aluminum amides such as tris(dimethylamido) aluminum (Al(N(CH₃)₂)₃).

Example hafnium-containing precursors for forming hafnium oxide films (HfOₓ) include hafnium tetrachloride (HfCl₄), tetrakis(diethylamino) hafnium (Hf(N(C₂H₅)₂)₄), and tetrakis(tert-butoxide) hafnium (Hf(OC(CH₃)₃)₄).

Examples of titanium-containing precursors for forming titanium oxide films (TiOₓ) include titanium tetrachloride (TiCl₄) and titanium isopropoxide (Ti(OCH(CH₃)₂)₄).

Examples of tungsten-containing precursors for forming tungsten oxide films (WOₓ) include tungsten hexafluoride (WF₆), tungsten hexachloride (WCl₆), bis(tert-butylimino) bis(dimethylamino) tungsten (C₁₂H₃₀N₄W), and tungsten hexacarbonyl (W(CO)₆).

Examples of tin-containing precursors for forming tin oxide films (SnOₓ) include tin tetrachloride (SnCl₄), tetramethyltin ((CH₃)₄Sn), tetraethyltin ((C₂H₅)₄Sn), dimethyltin dichloride ((CH₃)₂SnCl₂), dibutyl (dimethoxy) stannane (Bu₂Sn(OMe)₂), tetrakis (dimethylamido) tin (IV) (Sn(NMe₂)₄), dimethylamino dimethyl tin (Me₂Sn(NMe₂)₂), and dimethylamino trimethyl tin (Me₃Sn(NMe₂)), where Bu represents a butyl group (C₄H₉) and Me represents a methyl group (CH₃).

Examples of molybdenum-containing precursors for forming molybdenum oxide films (MoOₓ) include bis(tert-butylimino) bis(dimethylamino) molybdenum (C₁₂H₃₀MoN₄), molybdenum pentachloride (MoCl₅), molybdenum dioxide dichloride (MoO₂Cl₂), molybdenum oxytetrachloride (MoOCl₄), and molybdenum hexacarbonyl (Mo(CO)₆).

The term “substrate” may generally represent any object onto which a desired film can be deposited in a processing chamber.

The term “3D DRAM” is an acronym for three-dimensional dynamic random-access memory.

The term “3D NAND” is an acronym for three-dimensional NOT AND memory, and may generally represent memory architecture based upon NOT AND logic gates.

The term “3D NOR” is an acronym for three-dimensional NOT OR memory, and may generally represent memory architecture based upon NOT OR logic gates.

As mentioned above, atomic layer deposition (ALD) involves performing one or more deposition cycles to grow a thin film on a substrate surface. Example films that may be grown using ALD include various oxide films. PEALD utilizes a plasma to facilitate deposition of a film. During a PEALD oxide film deposition cycle, a film precursor is supplied to a processing chamber and adsorbs onto a substrate. Next, the processing chamber is purged to remove excess film precursor. Then, an oxidant is supplied to the processing chamber. A plasma is formed by application of radiofrequency (RF) power to electrodes within the processing chamber. The plasma forms reactive oxygen species. The reactive oxygen species react with the film precursor to form a layer of the oxide film. TALD utilizes substrate temperature to drive the chemical reactions that form the oxide film. Examples of oxide films that may be formed by ALD include films of silicon oxynitride (SiOₓN_{y}), silicon oxide (SiO₂), silicon oxycarbide SiCₓO_{2-y}, aluminum oxide (Al₂O₃), hafnium oxide (HfOₓ), titanium oxide (TiOₓ), tungsten oxide (WOₓ), tin oxide (SnOₓ), and molybdenum oxide (MoOₓ).

The fabrication of 3D circuit structures may involve the etching of high aspect ratio features through material layers of a substrate. Such etched structures also may be referred to as recessed features. For example, 3D NAND semiconductor devices utilize stacked pairs of material layers. One layer per material layer pair is a device layer. A device layer forms a wordline in a 3D memory structure. The other layer per material layer pair is a dielectric layer for electrical isolation. A stack comprising a plurality of such pairs of material layers may be referred to as a “mold stack”. Similar structures may be used to form 3D DRAM and 3D NOR devices.

High aspect ratio recesses may be formed in such stacks of material layers. Further processing may involve depositing oxide films on surfaces within the high aspect ratio recesses. ALD may be used to grow an oxide film conformally. As such, ALD can be used to deposit films within high aspect ratio recesses. However, conformal growth may not be desired in some applications. For example, where features on a 3D circuit structure reach high aspect ratios, the circuit structure can become vulnerable to breakdown at high energy levels. The yield, reliability, and/or electrical performance of semiconductor devices can be improved where the surfaces at greater depths in such high aspect ratio features receive additional thickness of insulating film growth. In various examples, the additional deposited film comprises a silicon oxide film, silicon nitride film, silicon oxynitride film, silicon carbide film or silicon oxycarbide film. However, growing such bottom-thick films using ALD may be challenging. For example, in a saturation regime, ALD films grow conformally. Below a saturation regime, more precursor may adsorb to the substrate relatively closer to an opening of a recessed feature than relatively deeper within the recessed feature. The resulting film has greater thickness relatively closer to an opening of a recessed feature than relatively deeper within the recessed feature.

Accordingly, examples are disclosed that relate to using an inhibitor in an ALD process to deposit a desired film at a relatively greater rate on surfaces at a relatively greater depth in a recessed feature compared to surfaces at a relatively lesser depth. The disclosed examples may provide controllable growth of a film that is thicker on the portion of the substrate surface relatively deeper within a recessed feature than relatively closer to an opening of the recessed feature. In some examples, the film may comprise a relatively sharp cutoff, such that the film is conformal deeper within the recess, until the cutoff location. While described in the context of a PEALD process, the disclosed examples also may be used in other ALD processes. Examples include TALD processes.

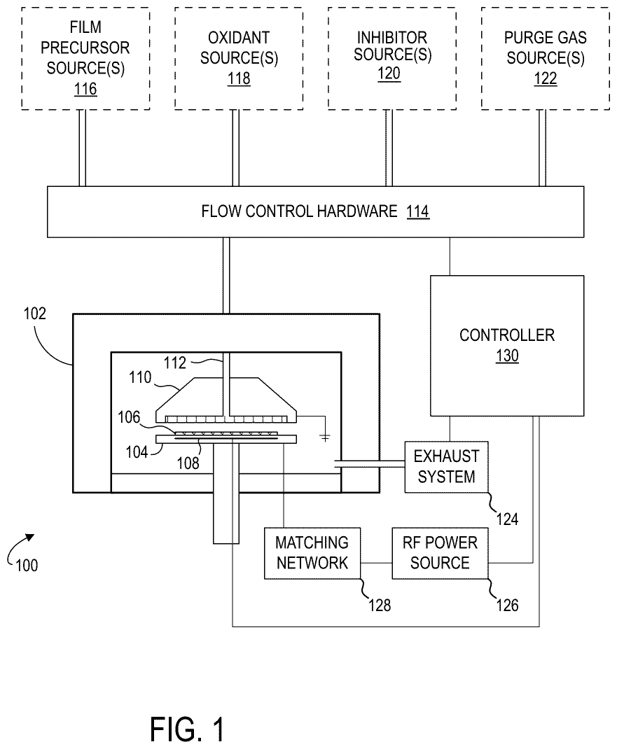

FIG. 1 shows a schematic view of an example ALD tool 100 for performing atomic layer deposition using an inhibitor. ALD tool 100 is configured as a PEALD tool. However, as mentioned above, the use of an inhibitor as disclosed herein also may be used to vary the conformality of a film deposited in other types of tools. Examples may include TALD and/or other ALD tools.

ALD tool 100 comprises a processing chamber 102 and a substrate support 104 within the processing chamber. Substrate support 104 is configured to support a substrate 106 disposed within processing chamber 102. Substrate support 104 may comprise a pedestal, a chuck, and/or any other suitable structure. Processing chamber 102 further may include a substrate heater 108. In other examples, a heater may be omitted, or may be located elsewhere within processing chamber 102.

ALD tool 100 further comprises a showerhead 110, a gas inlet 112, and flow control hardware 114. In other examples, a processing tool may comprise a nozzle or other apparatus for supplying gas into processing chamber 102, as opposed to or in addition to a showerhead. Flow control hardware 114 is connected to one or more film precursor source(s) 116, one or more oxidant source(s) 118, one or more inhibitor source(s) 120, and one or more purge gas source(s) 122.

Film precursor source(s) 116 may comprise any suitable film precursor or precursors that, when reacted with the oxidant, forms a desired film or films. The film may be an oxide film. Example silicon-containing oxide films include silicon oxide, silicon oxynitride, and silicon oxycarbide. Example metal oxide films include aluminum oxide, hafnium oxide, titanium oxide, tungsten oxide, tin oxide, and molybdenum oxide. Example film precursors for silicon-containing oxide films may include polysilanes, aminosilanes, halosilanes, and organosilanes. More detailed examples of silicon-containing film precursors are described above. Example film precursors for forming metal oxide films may include AlCl₃, Al(CH₃)₃, Al(OC₂H₅)₃, Al(N(CH₃)₂)₃, HfCl₄, Hf(N(C₂H₅)₂)₄, Hf(OC(CH₃)₃)₄, TiCl₄, Ti(OCH(CH₃)₂)₄, WF₆, WCl₆, W(CO)₆, bis(tert-butylimino) bis(dimethylamino) tungsten (C₁₂H₃₀N₄W), SnCl₄, (CH₃)₄Sn, (C₂H₅)₄Sn, (CH₃)₂SnCl₂, Bu₂Sn(OMe)₂, Sn(NMe₂)₄, Me₂Sn(NMe₂)₂, Me₃Sn(NMe₂), MoCl₅, MoO₂Cl₂, MoOCl₄, bis(tert-butylimino) bis(dimethylamino) molybdenum (C₁₂H₃₀MoN₄), and Mo(CO)₆. Oxidant source(s) 118 may comprise, for example, molecular oxygen (O₂), ozone (O₃) water vapor (H₂O), hydrogen peroxide (H₂O₂), nitrous oxide (N₂O) or a mixture of two or more thereof.

Inhibitor source(s) 120 comprises any suitable inhibitor that can be deposited nonconformally on a substrate and inhibit growth of an oxide film in an ALD process. Suitable inhibitors may include molecular hydrogen, nitrogen-containing inhibitors, fluorine-containing inhibitors, and carbon-containing inhibitors. Nitrogen-containing inhibitors may be used to inhibit metal film growth, for example. Suitable nitrogen-containing inhibitors may include nitrogen (N₂), ammonia (NH₃), amines, diamines, and aminoalcohols. Fluorine-containing inhibitors may be used to inhibit oxide film growth, such as silicon oxide, for example. Suitable fluorine-containing inhibitors may include F₂, NF₃, CF₄, SF₆, XeF₂, and fluorocarbons that are in gas phase under processing conditions. Carbon-containing inhibitors may primarily physisorb on substrate surfaces. Carbon-containing inhibitors compete with silicon-containing (or other) precursors for oxidation. Thus, carbon-containing precursors reduce the amount of oxygen that is available for oxidation of film precursors such as silicon. This slows the rate of film growth. Example carbon-containing inhibitors may include one or more of a thiol, an alkane, an alkene, an alkyne, a cyclic hydrocarbon, an alcohol, a diol, an aldehyde, an ester, an ether, a ketone, an alkyl halide, an alkyl amine, or an alkyl diamine.

Purge gas source(s) 122 may comprise any suitable inert gas. Examples include helium, neon, argon, krypton, xenon, and nitrogen. In some examples, one or more additional purge gas sources may be included. Each additional purge gas source may provide a different purge gas.

Flow control hardware 114 may be controlled to flow gas from film precursor source(s) 116, oxidant source(s) 118, inhibitor source(s) 120, and purge gas source(s) 122 into processing chamber 102 via gas inlet 112. Flow control hardware 114 may comprise one or more valves controllable to place a selected gas source or selected gas sources in fluid connection with gas inlet 112. In other examples, a processing chamber may comprise one or more additional gas inlets.

ALD tool 100 further comprises an exhaust system 124. Exhaust system 124 is configured to receive gases outflowing from processing chamber 102. In some examples, exhaust system 124 is configured to actively remove gas from processing chamber 102 and/or apply a partial vacuum. Exhaust system 124 may comprise any suitable hardware, including one or pumps.

ALD tool 100 further comprises an RF power source 126 that is electrically connected to substrate support 104. RF power source 126 is configured to form a plasma. When reacting adsorbed film precursor with an oxidant, RF power source 126 may form a plasma comprising the oxidant. Further, in some examples, a nitrogen-containing inhibitor or fluorine-containing inhibitor is deposited on a substrate by forming a plasma comprising the inhibitor. As such, RF power source 126 also may be used to form a plasma comprising an inhibitor. Showerhead 110 is configured as a grounded opposing electrode in this example. In other examples, RF power source 126 may supply RF power to showerhead 110, or to other suitable electrode structure. ALD tool 100 may include a matching network 128 for impedance matching of the RF power source 126. RF power source 126 may be configured for any suitable frequency and power. Examples of suitable frequencies include 400 kHz and 13.56 MHz. Examples of suitable powers include powers between 0 and 6500 watts. In some examples, RF power source 126 is configured to operate at a plurality of different frequencies and/or powers. In other examples, an ALD tool alternatively or additionally may comprise a remote plasma generator. A remote plasma generator may be used to generate a plasma away from a substrate being processed. This may allow reactive chemical species formed in the plasma to migrate to the substrate surface, while avoiding ion bombardment of the substrate surface.

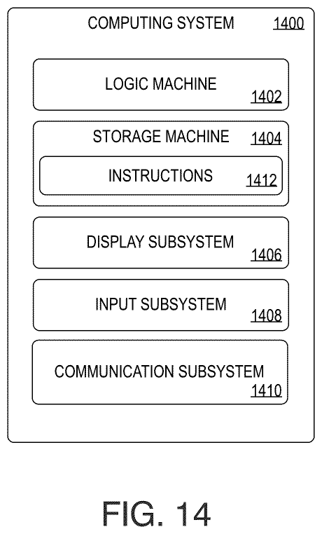

Controller 130 is operatively coupled to substrate heater 108, flow control hardware 114, exhaust system 124, and RF power source 126. Controller 120 is configured to control various functions of ALD tool 100 to perform an ALD process. For example, controller 130 is configured to operate substrate heater 108 to heat a substrate to a desired temperature. Controller 130 is also configured to operate flow control hardware 114 to flow a selected gas or mixture of gases at a selected rate into processing chamber 102. Controller 130 is further configured to operate exhaust system 124 to remove gases from processing chamber 102. Controller 130 may, for example, control exhaust system 124 and/or flow control hardware 114 to purge processing chamber 102. Furthermore, controller 130 is configured to operate RF power source 126 to form a plasma comprising the oxidant or form a plasma comprising an inhibitor, as well as to control any other suitable functions of ALD tool 100. Controller 130 may comprise any suitable computing system, examples of which are described below with reference to FIG. 14.

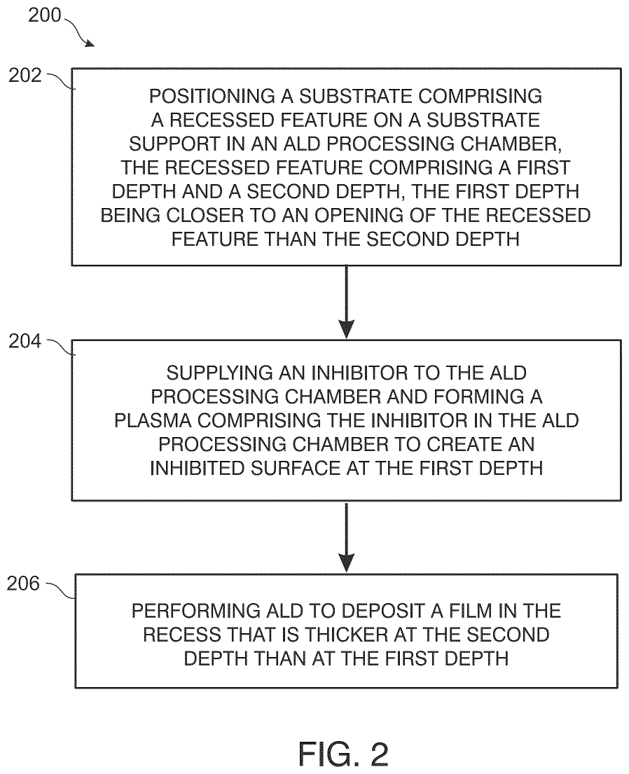

FIG. 2 shows a flow diagram depicting an example method 200 of nonconformally depositing by ALD a film on portions of a substrate located relatively deeper within a recessed feature. At 202, method 200 comprises positioning a substrate comprising a recessed feature on a substrate support in an ALD processing chamber. The recessed feature comprises a first depth and a second depth. The first depth is closer to an opening of the recessed feature than the second depth. At 204, method 200 comprises supplying an inhibitor to the ALD processing chamber and forming a plasma comprising the inhibitor in the ALD processing chamber. Processing is controlled to create an inhibited surface at the first depth. At 206, method 200 comprises performing ALD to deposit a film in the recess that is thicker at the second depth that at the first depth. Performing ALD may comprise performing PEALD, RPEALD, or TALD in various examples.

In some examples, an inhibitor may be deposited on the substrate by forming a plasma comprising the inhibitor in the absence of film precursor or reactant gases. In other examples, an inhibitor may be supplied to the processing chamber together with a reactant gas or a precursor gas. Examples include a film precursor or an oxidant.

A profile of a nonconformal adsorption of an inhibitor may be dependent on processing conditions. Example processing conditions include processing chamber pressure, partial pressure of the inhibitor, partial pressure of other gases, substrate temperature, gas flow rates, inhibitor exposure duration, and plasma characteristics. For example, the use of a capacitively coupled plasma may lead to directionality of ion bombardment on a substrate surface. The directionality may deposit a greater concentration of inhibitor on the recess wall at the first depth than at the second depth. One or more of increased RF power, increased inhibitor plasma pressure, increased inhibitor plasma gas flow rate, increased inhibitor plasma gas exposure time, or use of a lower frequency RF power component in addition to a higher frequency RF power component, may be used to increase a depth within the recess of inhibition on the recess wall. Various examples of arrangements of inhibitor, film precursor, and passivating cycles are described in more detail below. In some examples, a relatively sharp concentration gradient of adsorbed inhibitor may be achieved. This may provide for a relatively sharp film cutoff point along the sides of a recessed feature.

A plasma-applied inhibitor may chemisorb to the substrate surface. For example, fluorine-containing inhibitors may chemisorb to OH-terminated surface sites by replacing the H to form a fluorine-terminated surface. Nitrogen may react with a substrate surface to form an amino-terminated surface. Such inhibited surfaces may inhibit nucleation of an oxide film on the inhibited surface. As mentioned above, a fluorine-containing inhibitor may be used to inhibit growth of films such as silicon oxide, silicon nitride, silicon oxynitride, silicon carbide, and silicon oxycarbide. Likewise, a nitrogen-containing inhibitor may be used to inhibit metal film growth.

In some examples, the film precursor comprises a silicon-containing film precursor. In some such examples, the silicon-containing film precursor is reacted with an oxidant to form a silicon oxide-based film. In other such examples, the silicon-containing film precursor is reacted with a nitrogen-containing reactant to form a silicon nitride film. In further examples, the silicon-containing film precursor is reacted with an oxidant comprising nitrogen to form a silicon oxynitride film. An example of a nitrogen-containing precursor comprises ammonia. In further examples, the silicon-containing film precursor is reacted with an oxidant and a carbon-containing precursor to form a silicon oxycarbide film In other examples, the film precursor is selected to deposit a metal film or a metal oxide-based film. In some such examples, the metal precursor may comprise one or more of aluminum, hafnium, titanium, tungsten, tin, or molybdenum. Oxides of such metals can be formed by reacting the film precursors with an oxidant. In some examples, different film precursors may be used in different ALD cycles to deposit laminate films comprising alternating layers of two or more different compositions. The use of silicon oxide and metal oxide laminates or other film laminates can allows properties such as a dielectric constant, a band gap, and/or an elastic modulus of the film to be tailored by varying ratios of film layers.

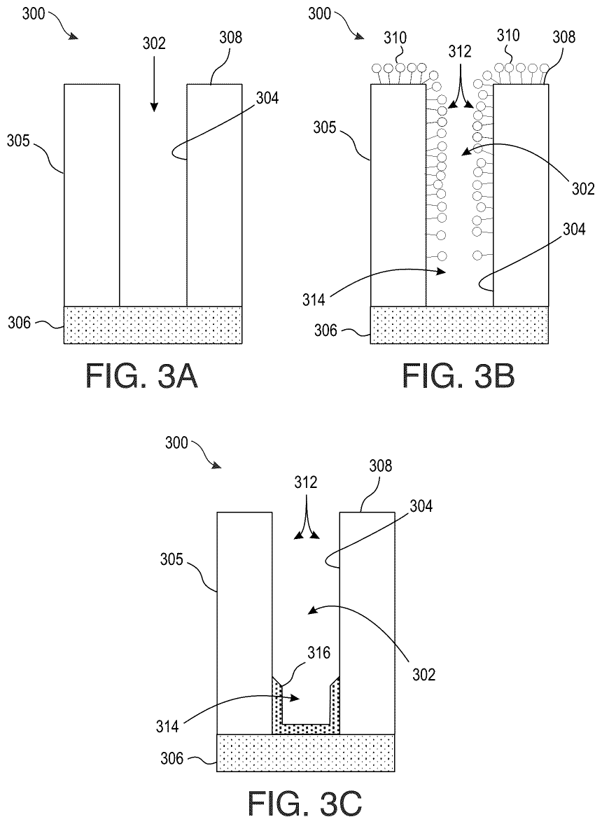

FIGS. 3A-3C schematically show structures formed in an example process of nonconformally depositing a film by ALD on portions of a substrate located relatively deeper within a recessed feature. First referring to FIG. 3A, a recessed feature 302 is formed in a substrate 300. Recessed feature 302 comprises a recess wall 304. In some examples, recessed feature 302 may comprise a hole etched in a 3D memory fabrication process. In such an example, recessed feature 302 may comprise a hole formed through a stack of alternating material layers formed on an underlying structure 306, such as a semiconductor wafer. In this example, such a stack of alternating layers is represented generically by region 305 of substrate 300. The recess extends into the substrate 300 from a surface 308 of the substrate 300.

FIG. 3B shows an example of adsorption of an inhibitor 310 onto surface 308 and recess wall 304 of the substrate. The term “inhibitor” is used herein to represent an inhibitor molecule introduced into a processing chamber, reactive inhibitor species formed in a plasma, and adsorbed inhibitor on a substrate surface.

In some examples, inhibitor 310 comprises a nitrogen-containing inhibitor, and forms a nitrogen-modified inhibited surface to inhibit metal film growth. In other examples, inhibitor 310 comprises a fluorine-containing inhibitor, and forms a fluorine-modified inhibited surface to inhibit oxide film growth.

Conditions are controlled to cause a greater concentration of inhibitor 310 to deposit at a first depth on a recess wall within the recessed feature 302 than at a second depth, wherein the first depth is closer to an opening of the recessed feature 302 than the second depth. This is indicated at example first depth 312 by a greater concentration of inhibitor 310 at a first depth within recessed feature. Likewise, a lesser concentration of inhibitor 310 is deposited at a second depth within the recessed feature 302 that is farther from the opening than the first depth. This is indicated at example second depth 314 by a lower concentration of inhibitor 310. Oxide film-forming reactions nucleate at a slower rate on inhibited surfaces. Thus, an oxide film growth rate is slower at first depth 312 compared to a growth rate at second depth 314. One or more of increased RF power, increased inhibitor plasma pressure, increased inhibitor plasma gas flow rate, increased inhibitor plasma gas exposure time, or use of a lower frequency RF power component in addition to a higher frequency RF power component, may be used to increase a depth of inhibition on the surfaces within the recessed feature. Sufficient concentrations of inhibitor may substantially prevent film growth on inhibited surfaces.

FIG. 3C schematically shows a film 316 that has deposited on substrate 300 by ALD. In some examples, film 316 may be deposited by PEALD. In other examples, film 316 may be deposited by another suitable ALD method, such as TALD or RPEALD.

FIG. 3C also illustrates inhibitor 310 having been removed by passivation. Example ALD cycles are described in more detail below. Example silicon-containing oxide films include silicon oxide, silicon oxynitride, and silicon oxycarbide. Example metal oxide films include aluminum oxide, hafnium oxide, titanium oxide, tungsten oxide, tin oxide, and molybdenum oxide. Example laminate films include molybdenum/silicon oxide laminates and tungsten/silicon oxide laminates. As described above, oxide film growth may be relatively slower on surfaces with a greater concentration of deposited inhibitor and relatively faster on surface with a lesser concentration of deposited inhibitor. Thus, as depicted in FIG. 3C, film 316 growth is relatively slower at first depth 312 within recessed feature 302 and relatively faster at second depth 314 within recessed feature 302. As a result, deposited film 316 is thicker at example second depth 314 than at first depth 312. Further, film 316 has a relatively sharp cutoff corresponding to a depth of deposited inhibitor.

In some examples, recessed feature 302 may exhibit a high aspect ratio (HAR). A feature exhibits a HAR if the ratio of the feature's vertical dimension to the feature's horizontal dimension is greater than or equal to 20:1. In some examples recessed feature 302 may have a HAR that is greater than or equal to 20:1 and less than or equal to 200:1.

In some examples, film 316 may exhibit a film thickness of about 5 Angstroms to about 20 Angstroms. In examples in which recessed feature 302 is formed in a 3D memory structure, film 316 may extend upwardly along the sides of the recessed feature to a height of ten wordlines or less.

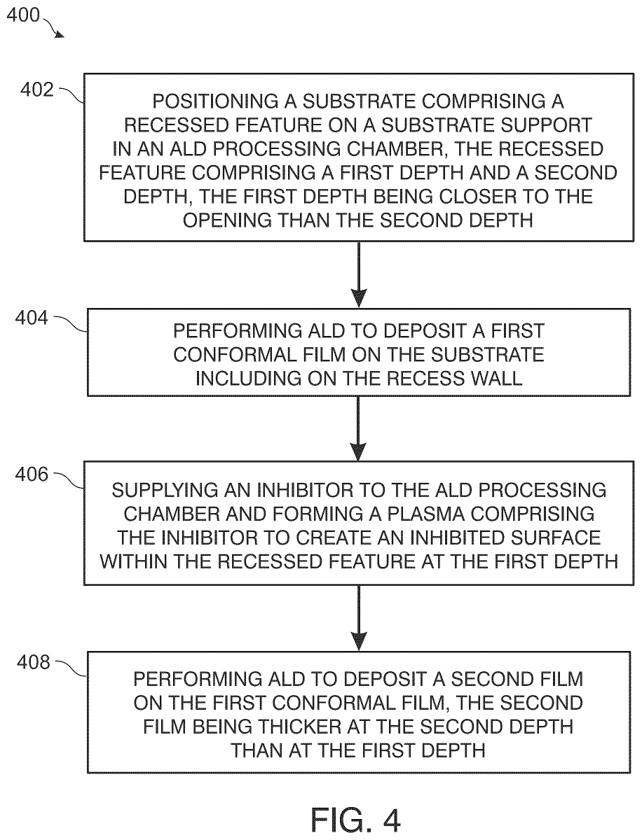

In some examples, a film having a greater thickness at a substrate surface located relatively more deeply in a recessed feature can be deposited over a conformal film within the recessed feature. FIG. 4 shows a flow diagram depicting an example method of depositing such a film by ALD. At 402, method 400 comprises positioning a substrate comprising a recessed feature on a substrate support in an ALD processing chamber. The recessed feature comprises a recess wall extending into the substrate from an opening of the recessed feature. The recessed feature further comprises a first depth and a second depth, the first depth being closer to the opening than the second depth. At 404, method 400 comprises performing ALD to deposit a first conformal film on the substrate including on the recess wall within the recessed feature. At 406, method 400 comprises supplying an inhibitor to the ALD processing chamber and forming a plasma comprising the inhibitor in the ALD processing chamber to create an inhibited surface within the recessed feature at the first depth. At 408, method 400 comprises performing ALD to deposit a second film on the first conformal film. The second film is thicker at the second depth than at the first depth. In some examples, the second film may be deposited by PEALD.

As discussed above, the inhibitor plasma can inhibit the adsorption of reactants to the substrate surface. One or more of increased RF power, increased inhibitor plasma pressure, increased inhibitor plasma gas flow rate, increased inhibitor plasma gas exposure time, or use of a lower frequency RF power component in addition to a higher frequency RF power component, can be used to increase the depth of inhibition on the surfaces of the recessed feature.

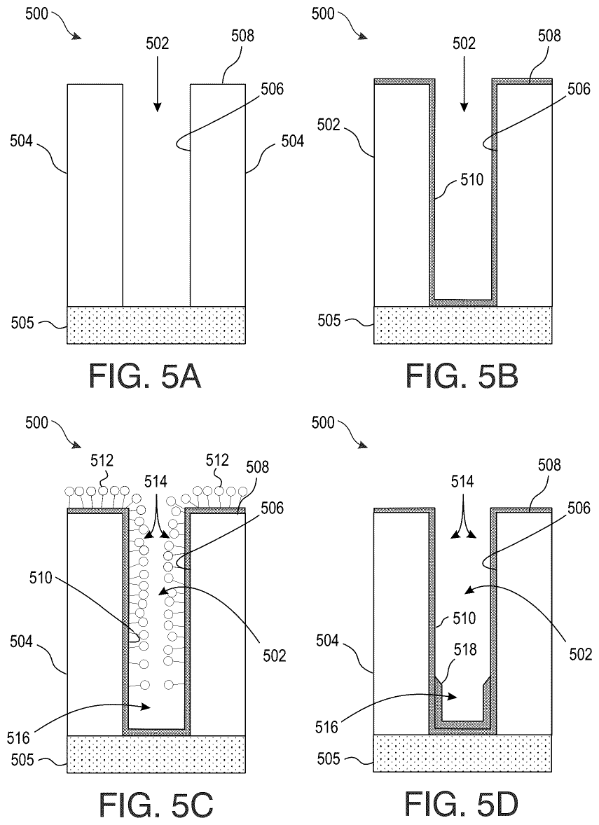

FIGS. 5A-5D schematically show structures formed in an example process of depositing by ALD a first conformal film on a substrate including a recessed feature, and nonconformally depositing by ALD a second film on portions of the substrate located relatively deeper within the recessed feature. First referring to FIG. 5A, a substrate 500 comprises a recessed feature 502. Recessed feature 502 may comprise a hole etched in a 3D memory fabrication process. In such an example, recessed feature 502 may comprise a hole formed through a stack of alternating material layers. In this example, such a stack of alternating layers is represented generically by region 504 formed on an underlying structure 505, such as a silicon wafer. Recessed feature comprises a recess wall 506 that extends into the substrate 500 from a substrate surface 508.

FIG. 5B shows an example of deposition of a first conformal film 510 onto substrate 500 using ALD. In some examples, first conformal film 510 may be deposited by PEALD. In other examples, first conformal film 510 may be deposited by another suitable ALD method, such as TALD or RPEALD. First conformal film 510 comprises any suitable film material, including silicon oxides, silicon nitrides, silicon oxynitrides, silicon carbide, silicon oxycarbides, metal oxides, and metals described above.

FIG. 5C shows an example of adsorption of an inhibitor 512 onto first conformal film 510. Conditions are controlled to cause a greater concentration of inhibitor 512 to deposit at a first depth within the recessed feature 502 than at a second depth, wherein the first depth is closer to an opening of the recessed feature than the second depth. This is indicated at depth 514 by a greater concentration of inhibitor 512. Additionally, a lesser concentration of inhibitor 512 is deposited at a greater depth within the recessed feature 502. This is indicated at depth 516 by a lower concentration of inhibitor 512. As discussed above, a plasma comprising the inhibitor may be used to deposit the inhibitor 512.

FIG. 5D schematically shows a second film 518 deposited on first conformal film 510. The inhibitor 506 has been removed by passivation. Second film 518 may be formed by performing one or more ALD cycles with inhibitor 506. In some examples, second film 518 may be deposited by PEALD. In other examples, second conformal film 518 may be deposited by another suitable ALD method, such as TALD or RPEALD. Second film 518 comprises any suitable film material, including silicon oxides, silicon oxynitrides, silicon oxycarbides, silicon carbide, metal oxides, and metals. As described above, film growth may be relatively slower on surfaces with a greater concentration of deposited inhibitor and relatively faster on surface with a lesser concentration of deposited inhibitor. Thus, as depicted in FIG. 5D, second film 518 growth is relatively slower at depth 514 within recessed feature 502 and relatively faster at depth 516 within recessed feature 502. As a result, second film 518 is thicker on the portion of first conformal film 510 at the second depth 516 than at the first depth 514.

In some examples, recessed feature 502 may exhibit a high aspect ratio (HAR) that is greater than or equal to 20:1. In some examples recessed feature 502 may have a HAR that is greater than or equal to 20:1 and less than or equal to 200:1.

In some examples, film 510 may be deposited so as to exhibit a film thickness of about 40 Angstroms to about 90 Angstroms. In more specific examples, film 510 may exhibit a film thickness of about 60 Angstroms to about 70 Angstroms. In some examples, film 510 may exhibit a film thickness of about 5 Angstroms to about 20 Angstroms. In examples in which recessed feature 502 is formed in a 3D memory structure, film 518 may extend upwardly along the sides of the recessed feature to a height of ten wordlines or less.

As shown in FIGS. 5A-5D, first conformal film 510 and second film 518 may comprise a same material. In other examples, first conformal film 510 and second film 518 may have different compositions. For example, first conformal film 510 may comprise one of silicon oxide, silicon nitride, or silicon oxynitride, and second film 518 may comprise a different one of these materials.

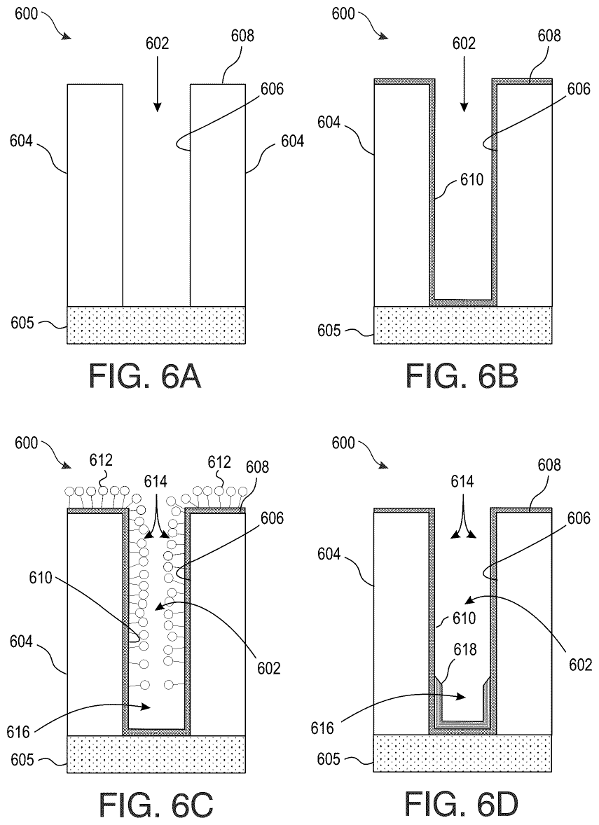

FIGS. 6A-6D illustrate another example of the deposition of a first conformal film, followed by deposition of a second film that is nonconformal. In this example, the second film is a laminate film. First referring to FIG. 6A, a substrate 600 comprises a recessed feature 602 formed in a surrounding material region 604 that is formed on an underlying structure 605, such as a silicon wafer. Recessed feature 602 comprises a recess wall 606 extending into substrate 600 from a substrate surface 608.

FIG. 6B shows an example of deposition of a first conformal film 610 onto substrate 600 using ALD. First conformal film 610 comprises any suitable film material, including silicon oxides, silicon nitrides, silicon oxynitrides, silicon carbide, silicon oxycarbides, metal oxides, and metals described above. In some examples, first conformal film 610 may be deposited by PEALD. In other examples, first conformal film 610 may be deposited by another suitable ALD method, such as TALD or RPEALD.

FIG. 6C shows an example of adsorption of an inhibitor 612 onto first conformal film 610. Conditions are controlled to cause a greater concentration of inhibitor to deposit at a first depth within the recessed feature 602, as described above. This is indicated at example first depth 614 by a greater concentration of inhibitor 612. Additionally, a lesser concentration of inhibitor 612 is deposited at a second depth within the recessed feature 602. This is indicated at example second depth 616 by a lower concentration of inhibitor 612. The first depth 616 is closer to an opening of the recessed feature than the second depth 614. As discussed above, a plasma comprising the inhibitor may be used to deposit the inhibitor.

FIG. 6D schematically shows a second film 618 deposited on first conformal film 610. The deposited inhibitor 612 has been removed by passivation. Second film 618 comprises a laminate film. Second film 618 may be formed by alternating cycles of ALD for different oxide materials. Examples include alternating cycles of silicon oxide deposition and metal oxide deposition. In some examples, a different inhibitor may be used for cycles of different oxide materials. In some examples, second film 618 may be deposited by PEALD. In other examples, second film 618 may be deposited by another suitable ALD method, such as TALD or RPEALD.

As described above, film growth is relatively slower on surfaces with a greater concentration of deposited inhibitor and relatively faster on surface with a lesser concentration of deposited inhibitor. Thus, as depicted in FIG. 6D, second film 618 growth is relatively slower at the first depth 614 within recessed feature 602 and relatively faster at the second depth 616 within recessed feature 602. As a result, second film 618 is thicker at the second depth 616 than at the first depth 614.

In some examples, recessed feature 602 may exhibit a high aspect ratio (HAR) that is greater than or equal to 20:1. In some examples recessed feature 602 may have a HAR that is greater than or equal to 20:1 and less than or equal to 200:1.

In some examples, film 610 may be deposited so as to exhibit a film thickness of about 40 Angstroms to about 90 Angstroms. In more specific examples, film 610 may exhibit a film thickness of about 60 Angstroms to about 70 Angstroms. In some examples, film 610 may exhibit a film thickness of about 5 Angstroms to about 20 Angstroms. In examples in which recessed feature 602 is formed in a 3D memory structure, film 618 may extend upwardly along the sides of the recessed feature to a height of ten wordlines or less.

To deposit a film in the relatively deeper portions of a recessed feature using ALD processing compared to a relatively less deep portion closer to an opening of the recessed feature, a plurality of ALD cycles are performed where at least one ALD cycle comprises an ALD cycle comprising an inhibitor. In some examples, each ALD cycle comprises supplying of an inhibitor. In other examples, an inhibitor may be supplied in some, but not all ALD cycles. ALD cycles comprising supplying of an inhibitor and ALD cycles that omit an inhibitor may be performed in any suitable order. Further, one or more passivation cycles may be used to remove an inhibitor from a substrate surface in some examples.

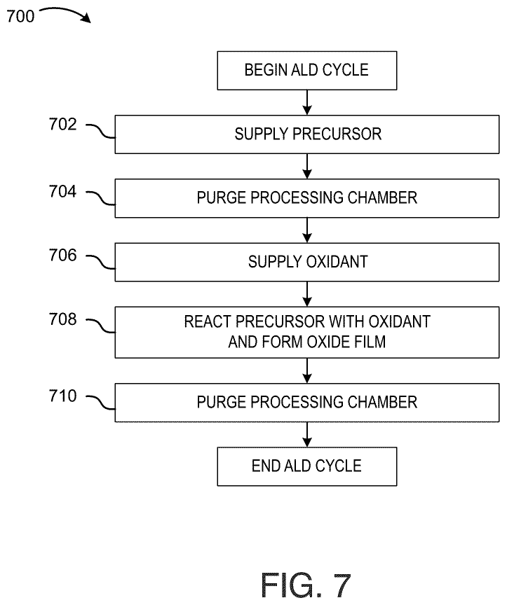

FIG. 7 shows a flow diagram of an example ALD cycle 700 that omits supplying of an inhibitor. ALD cycle 700 may be performed any suitable number of times to form an oxide film on a substrate disposed in a processing chamber of an ALD tool. Suitable oxide films include silicon oxide, silicon oxynitride, silicon oxycarbide, aluminum oxide (Al₂O₃), hafnium oxide (HfOₓ), titanium oxide (TiOₓ), tungsten oxide (WOₓ), tin oxide (SnOₓ), and molybdenum oxide (MoOₓ) films. ALD tool 100 is an example tool for performing ALD cycle 700.

At 702, ALD cycle 700 comprises supplying a film precursor into a processing chamber. Example precursors for various films are listed above.

At 704, the processing chamber is purged to remove excess film precursor. In some examples, an inert gas may be flowed into the processing chamber during a purge. Continuing, at 706, ALD cycle 700 comprises supplying an oxidant into the processing chamber. Any suitable oxidant that can react with the film precursor to form an oxide film can be used. Suitable oxidants include O₂, O₃, H₂O, and H₂O₂.

At 708, ALD cycle 700 comprises reacting the film precursor with the oxidant to form a layer of oxide film on the substrate. In examples that involve PEALD, a plasma may be used to react the film precursor with the oxidant. For example, the reaction can be performed using a RF power source to form a plasma comprising the oxidant. The RF power source may be operated at any suitable frequency (e.g., 400 kHz, 13.56 MHz in some examples) and power (e.g., between 0 and 7000 watts in some examples). Oxidant is converted to oxygen-containing reactive species via the plasma. The oxygen-containing reactive species can then react with the adsorbed film precursor to form a layer of oxide film on the substrate. In some examples, a purge 710 is performed following 708 to complete the ALD cycle. When a RF power source is used to form a plasma, the purge may be performed after extinguishing the plasma. In other examples, a purge may be omitted.

Further, in some examples, the substrate is heated via a substrate heater during processing. In some examples, the substrate heater may be heated to a temperature within a range of 50° C. to 750° C. In other examples, temperatures outside of these ranges may be used. In other examples, an ALD cycle may be performed using TALD. In such examples, the reaction at may be performed using thermal energy.

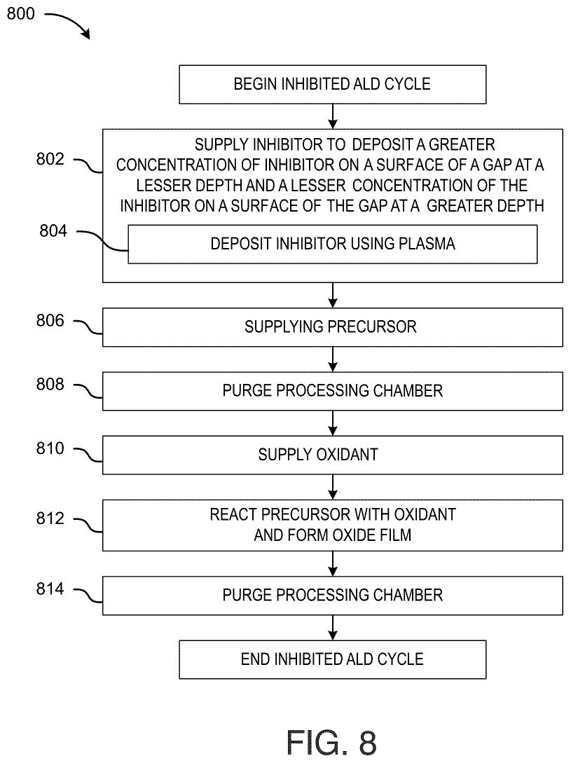

FIG. 8 shows an example ALD cycle comprising an inhibitor 800. ALD cycle comprising an inhibitor 800 may be performed by an ALD tool comprising a processing chamber in which the substrate is disposed. ALD cycle comprising an inhibitor 800 may be used to nonconformally deposit a film. Examples include film 314 of FIG. 3C, film 514 of FIG. 5D, and film 614 of FIG. 6D.

ALD cycle comprising an inhibitor 800 comprises, at 802, supplying an inhibitor into the processing chamber. The supplying of the inhibitor is controlled to deposit a greater amount of inhibitor at a surface of the recessed feature at a lesser depth and a lesser amount of inhibitor at a surface of the recessed feature at a greater depth. One or more of increased RF power, increased inhibitor plasma pressure, increased inhibitor plasma gas flow rate, increased inhibitor plasma gas exposure time, or use of a lower frequency RF power component in addition to a higher frequency RF power component, increases the depth of inhibition on the surfaces of the recessed feature.

Any suitable inhibitor may be used. Examples include one or more of molecular hydrogen, a nitrogen-containing inhibitor, a fluorine-containing inhibitor, or a carbon-containing inhibitor. Suitable nitrogen-containing inhibitors include N₂, NH₃, amines, diamines, and aminoalcohols. Suitable fluorine-containing inhibitors include F₂, NF₃, SF₆, HF, XeF₂, and fluorocarbons such as CF₄ or C₂F₆. Suitable carbon-containing inhibitors may include one or more of a thiol, an alkane, an alkene, an alkyne, a cyclic hydrocarbon, an alcohol, a diol, an aldehyde, an ester, an ether, a ketone, an alkyl halide, an alkyl amine, or an alkyl diamine. In some examples, a substrate heater may be heated to a temperature within a range of 50° C. to 750° C.

In some examples, as indicated at 804, supplying the inhibitor comprises forming a plasma to deposit the inhibitor. For example, the ALD tool may control a RF power source to form a plasma comprising the inhibitor. Suitable inhibitors for plasma deposition include molecular hydrogen, nitrogen-containing inhibitors, fluorine-containing inhibitors, and carbon-containing inhibitors. Nitrogen-containing inhibitors may be used to inhibit metal film growth. Fluorine-containing inhibitors may be used to inhibit oxide film growth. The RF power source may be operated at any suitable frequency (e.g., 400 kHz, 13.56 MHz) and power (e.g., between 0 and 7000 watts). The inhibitor may be converted to a reactive species by the plasma which may help chemisorption of the inhibitor. For example, nitrogen-containing reactive species created by the plasma may form a nitride surface upon deposition to inhibit metal film deposition. Similarly, fluorine-containing reactive species may form a fluoride surface to inhibit oxide film deposition. Carbon-containing reactive species may physiadsorb to the surface of the substrate, and then compete with film precursor for oxidant, thereby slowing the rate of oxidation of the film precursor.

At 806, ALD cycle comprising an inhibitor 800 comprises supplying a film precursor into a processing chamber. Suitable film precursors are described in more detail above. ALD cycle comprising an inhibitor 800 further comprises purging the processing chamber at 808.

ALD cycle comprising an inhibitor 800 further comprises supplying an oxidant into the processing chamber at 810. Suitable oxidants include 02, 03, H₂O, and H₂O₂. At 812, ALD cycle comprising an inhibitor 800 comprises reacting the film precursor with the oxidant to form a layer of oxide film on the substrate. In examples that involve PEALD, a plasma may be used to react the film precursor with the oxidant. For example, the reaction can be performed using a RF power source to form a plasma comprising the oxidant. The RF power source may be operated at any suitable frequency (e.g., 400 kHz, 13.56 MHz) and power (e.g., between 0 and 7000 watts). The oxidant can be converted to oxygen-containing reactive species via the plasma. The oxygen-containing reactive species can then react with the adsorbed monolayer of film precursor to form a layer of oxide film on the substrate. Suitable oxide films include silicon oxide, silicon oxynitride, silicon oxycarbide, aluminum oxide (Al₂O₃), hafnium oxide (HfOₓ), titanium oxide (TiOₓ), tungsten oxide (WOₓ), tin oxide (SnOₓ), and molybdenum oxide (MoOₓ) films. Due to the inhibitor deposited at 802, the oxide film grows nonconformally. As such, a relatively thicker oxide film layer may be formed on a surface in the recessed feature at a relatively greater depth corresponding to the lesser concentration of inhibitor. Likewise, a relatively thinner oxide film layer may be formed on a surface in the recessed feature at a relatively lesser depth corresponding to the greater concentration of inhibitor.

After reacting the film precursor with the oxidant, ALD cycle comprising an inhibitor 800 comprises purging the processing chamber at 814 to complete the ALD cycle comprising an inhibitor 800. In some examples, a purge may be omitted.

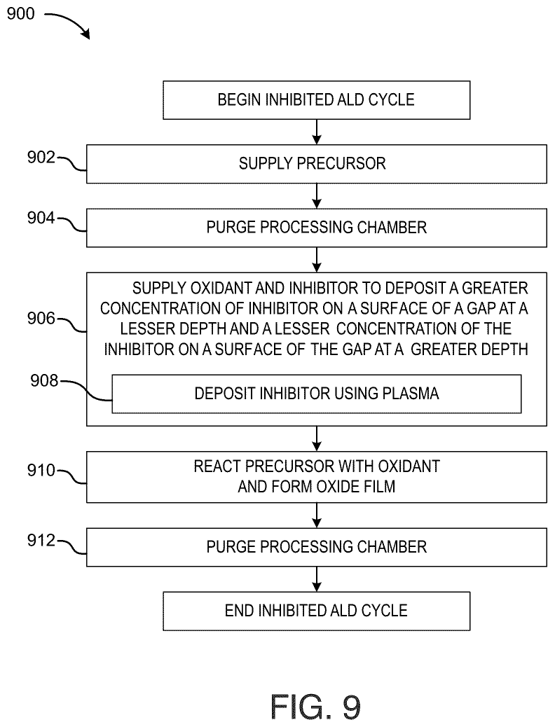

FIG. 9 shows a flow diagram for another example ALD cycle comprising an inhibitor 900 in which the inhibitor is supplied with the oxidant. In contrast with method 800, method 900 supplies inhibitor with the oxidant, rather than prior to supplying of the oxide. ALD cycle comprising an inhibitor 900 may be performed by an ALD tool comprising a processing chamber in which the substrate is disposed.

ALD cycle comprising an inhibitor 900 comprises, at 902, supplying a film precursor into a processing chamber. Suitable film precursors Include those listed above. At 904, the processing chamber is purged to remove excess film precursor.

ALD cycle comprising an inhibitor 900 further comprises supplying both an oxidant and an inhibitor into the processing chamber at 906. Suitable oxidants include O₂, O₃, H₂O, and H₂O₂. The inhibitor supplied at 906 deposits a greater concentration of inhibitor at a surface of the recessed feature at a lesser depth and a lesser concentration of inhibitor at a surface of the recessed feature at a greater depth. Any suitable inhibitor may be used, such as a nitrogen-containing inhibitor or a fluorine-containing inhibitor.

At 910, ALD cycle comprising an inhibitor 900 comprises reacting the film precursor with the oxidant to form a layer of oxide film on the substrate. In examples that involve PEALD, a plasma may be used to react the film precursor with the oxidant. For example, the reaction can be performed using a RF power source to form a plasma comprising the oxidant. The RF power source may be operated at any suitable frequency (e.g., 400 kHz, 13.56 MHz) and power (e.g., between 0 and 7000 watts). The oxidant can be converted to oxygen-containing reactive species via the plasma. The oxygen-containing reactive species can then react with the adsorbed film precursor to form a layer of oxide film on the substrate. Due to the inhibitor supplied at 906, the oxide film grows nonconformally. As such, a relatively thicker oxide film layer may be formed on a surface in the recessed feature at a greater depth corresponding to the lesser concentration of inhibitor. Likewise, a relatively thinner oxide film layer may be formed on a surface in the recessed feature at a lesser depth corresponding to the greater concentration of inhibitor.

After reacting the film precursor with the oxidant, ALD cycle comprising an inhibitor 900 comprises purging the processing chamber at 912 to complete the ALD cycle comprising an inhibitor 900. In some examples, a purge may be omitted.

ALD cycle comprising an inhibitor 900 may be used to nonconformally deposit a film. Examples include film 314 of FIG. 3C, film 514 of FIG. 5D, and film 614 of FIG. 6D.

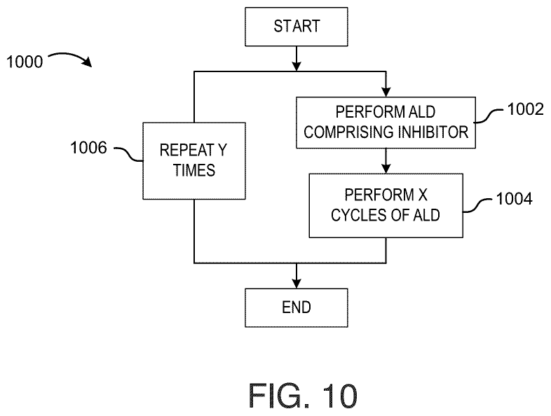

ALD processing may involve repeated ALD cycles. Such repeated ALD cycles may be performed in any suitable manner. FIG. 10 shows a flow diagram of an example method 1000 for performing ALD processing on a substrate. Method 1000 comprises one or more ALD cycles comprising an inhibitor to help achieve nonconformal oxide film growth and controllably deposit an oxide film that is thicker at a second depth within a recessed feature than at a first depth, wherein the first depth is closer to the opening of the recessed feature than the second depth. Suitable oxide films include silicon oxide, silicon oxynitride, silicon oxycarbide, aluminum oxide (Al₂O₃), hafnium oxide (HfOₓ), titanium oxide (TiOₓ), tungsten oxide (WOₓ), tin oxide (SnOₓ), and molybdenum oxide (MoOₓ) films.

For example, and as depicted in FIG. 10, method 1000 performs an ALD cycle comprising an inhibitor at 1002. The ALD cycle comprising an inhibitor may comprise supplying of any suitable inhibitor, such as a nitrogen-containing inhibitor or a fluorine-containing inhibitor. In some examples, the inhibitor may be deposited on the substrate by forming a plasma comprising the inhibitor. The inhibitor deposits a relatively greater concentration of inhibitor at a lesser depth within the recessed feature and a lesser concentration of inhibitor at a greater depth within the recessed feature. ALD cycle comprising an inhibitor 800 and ALD cycle comprising an inhibitor 900 are examples of ALD cycles that may be performed at 1002 to supply an inhibitor.

At 1004, method 1000 performs a number “X” of ALD cycles omitting an inhibitor. At least some of the inhibitor deposited at 1002 may remain on the substrate through one or more of the ALD cycles performed at 1004. ALD cycle 700 is an example of an ALD cycle that may be performed at 1004. Any suitable number of ALD cycles may be performed with any suitable ratio 1:X of ALD cycles comprising an inhibitor to ALD cycles omitting an inhibitor. For example, if a 1:1 ratio is desired, the ALD cycle may be performed once at 1004. As another example, two ALD cycles may be performed at 1004 resulting in a 1:2 ratio. In some examples, X=0 and no ALD cycles are performed omitting an inhibitor. A greater ratio of ALD cycles with inhibitor to ALD cycles that omit supplying inhibitor may result in a greater degree of oxide film nonconformality compared to a lower ratio.

The ALD cycles performed at 1002 and 1004 may be repeated any suitable number “Y” of times, as indicated at 1006. Once a sufficient oxide film thickness has been achieved, method 1000 terminates. Due to inhibitor supplied at 1002, the oxide film grows nonconformally to deposit at lower portions of the recessed feature.

Various process variables may be adjusted to affect a degree of film conformality. As described above, a ratio of ALD cycles omitting an inhibitor to ALD cycles that include supplying an inhibitor can be adjusted to control the degree of nonconformal growth. As another example, varying a time of exposure to the inhibitor may vary a conformality of the oxide film. Additionally, one or more passivation steps may be performed during ALD processing to remove residual inhibitor from the substrate. In some examples, when performing ALD with a fluorine-containing inhibitor, the one or more passivation steps may help to avoid incorporation of fluorine into the oxide film. In some examples, a passivation step can be performed at the end of ALD processing. In some examples, passivation steps additionally or alternatively are performed between ALD cycles.

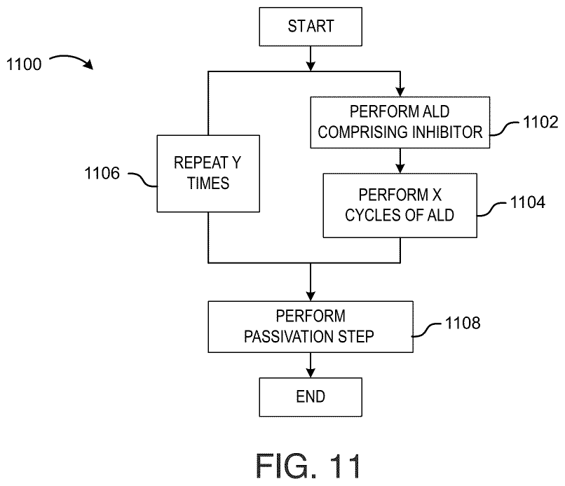

FIG. 11 shows a flow diagram of an example method 1100 for performing ALD processing with a passivation step. Method 1100 may be used to deposit an oxide film on a substrate comprising a recessed feature. Method 1100 comprises one or more ALD cycles comprising an inhibitor to grow the oxide film nonconformally at lower portions of the recessed feature corresponding to lesser concentrations of inhibitor. Suitable oxide films include silicon oxide, silicon oxynitride, silicon oxycarbide, aluminum oxide (Al₂O₃), hafnium oxide (HfOₓ), titanium oxide (TiOₓ), tungsten oxide (WOₓ), tin oxide (SnOₓ), and molybdenum oxide (MoOₓ) films.

Method 1100 performs an ALD cycle comprising an inhibitor at 1102. ALD cycle comprising an inhibitor 800 and ALD cycle comprising an inhibitor 900 are examples of ALD cycles that may be performed at 1102. ALD cycle comprising an inhibitor 1102 may comprise supplying of any suitable inhibitor. Examples include a nitrogen-containing inhibitor or a fluorine-containing inhibitor. In some examples, the inhibitor may be deposited on the substrate by forming a plasma comprising the inhibitor.

At 1104, method 1100 performs a number “X” of ALD cycles omitting an inhibitor. ALD cycle 700 is an example of an ALD cycle that may be performed at 804. In some examples, method 1100 may perform a number X between 1 and 20 ALD cycles at 1104. In other examples, any suitable number X of ALD cycles may be performed at 1104. The ALD cycles performed at 1102 and 1104 may be repeated any suitable number “Y” of times, as indicated at 806. Due to inhibitor supplied at 1102, the oxide film grows nonconformally to deposit at lower portions of the recessed feature.

Once a sufficient oxide film thickness has been achieved, method 1100 may proceed to 1108 and perform a passivation step. Passivation helps remove residual inhibitor from the substrate. For example, an inhibitor that chemisorbs to the substrate at 1102 may at least partially remain on the substrate after performing the X ALD cycles at 1104. Inhibitor remaining on the substrate may affect subsequent processing. Thus, the passivation step may be performed at 1108 to remove the chemisorbed inhibitor. After performing the passivation step at 1108, method 1100 may terminate. Florine-containing inhibitors and nitrogen-containing inhibitors may be removed by treatment with H₂, O₂, or a combination thereof. A plasma and/or thermal energy may be used to facilitate the passivation reaction. In other examples, an inhibitor may be removed without a passivation cycle. For example, a carbon-containing inhibitor may be removed by oxidation during film precursor oxidation.

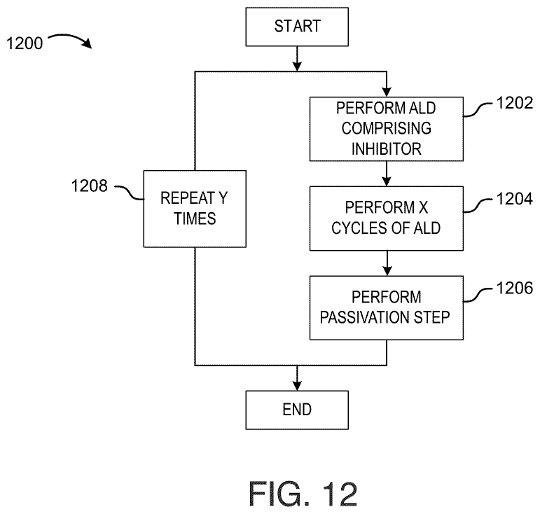

FIG. 12 shows a flow diagram of another example method 1200 for performing ALD processing with a passivation step. Method 1200 comprises a plurality of ALD cycle comprising an inhibitor 1202 to help achieve nonconformal oxide film growth and deposit the oxide film at lower portions of the recessed feature. Suitable oxide films include silicon oxide, silicon oxynitride, silicon oxycarbide, aluminum oxide (Al₂O₃), hafnium oxide (HfOₓ), titanium oxide (TiOₓ), tungsten oxide (WOₓ), tin oxide (SnOₓ), and molybdenum oxide (MoOₓ) films.

Method 1200 comprises performing an ALD cycle comprising an inhibitor 1202. ALD cycle comprising an inhibitor 800 and ALD cycle comprising an inhibitor 900 are examples of ALD cycles comprising an inhibitor that may be performed at 1202. ALD cycle comprising an inhibitor 1202 may comprise supplying of any suitable inhibitor. Examples include a nitrogen-containing inhibitor or a fluorine-containing inhibitor. More detailed examples of such inhibitors are described above. The inhibitor deposits a relatively greater concentration of inhibitor at a lesser depth within the recessed feature and a lesser concentration of inhibitor at a greater depth within the recessed feature. Examples of process variables that may be controlled to achieve such inhibitor deposition also are described above.

At 1204, method 900 performs a number “X” of ALD cycles omitting an inhibitor. ALD cycle 700 is an example of an ALD cycle that may be performed at 1204. Any suitable number X of ALD cycles may be performed at 1204.

After performing an ALD cycle comprising an inhibitor at 1202 and X ALD cycles at 1204, method 1200 comprises performing a passivation step at 1206. As described above, a passivation step can be performed to remove residual inhibitor from the substrate.

The ALD cycles performed at 1202 and 1204, and the passivation step performed at 1206 may be repeated any suitable number “Y” of times, as indicated at 1208. Thus, method 1200 includes one passivation step per ALD cycle comprising an inhibitor. Once a sufficient oxide film thickness has been achieved, method 1200 may terminate. Due to inhibitor supplied at 1202, the oxide film grows nonconformally to deposit at lower portions of the recessed feature. Further, a number Y of passivation steps are performed which may help avoid incorporation of inhibitor into the oxide film.

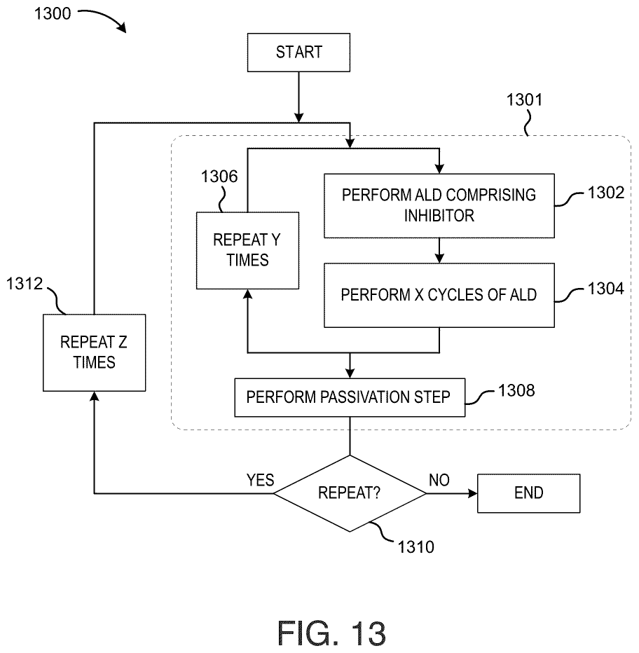

In some examples, passivation is performed at different intervals. FIG. 13 shows a flow diagram for an example method 1300 for performing one or more supercycles 1301. Each supercycle 1301 comprises at least one ALD cycle comprising an inhibitor and at least one passivation step.

Method 1300 comprises a plurality of ALD cycle comprising an inhibitor to help achieve nonconformal oxide film growth and fill the recessed feature without forming a seam. Suitable oxide films include silicon oxide, silicon oxynitride, silicon oxycarbide, aluminum oxide (Al₂O₃), hafnium oxide (HfOₓ), titanium oxide (TiOₓ), tungsten oxide (WOₓ), tin oxide (SnOₓ), and molybdenum oxide (MoOₓ) films.

As part of a supercycle 1301, method 1300 performs an ALD cycle comprising an inhibitor 1302. ALD cycle comprising an inhibitor 1302 may supply any suitable inhibitor, such as a nitrogen-containing inhibitor or a fluorine-containing inhibitor. In some examples, the inhibitor may be deposited on the substrate using a plasma. The inhibitor deposits a relatively greater concentration of inhibitor at a lesser depth within the recessed feature and a lesser concentration of inhibitor at a greater depth within the recessed feature. ALD cycle comprising an inhibitor 800 and ALD cycle comprising an inhibitor 900 are examples of ALD cycles comprising an inhibitor that may be performed at 1302.

At 1304, supercycle 1301 comprises performing a number “X” of ALD cycles omitting an inhibitor. ALD cycle 700 is an example of an ALD cycle that may be performed at 1304. Any suitable number X of ALD cycles may be performed at 1304. Further, the ALD cycles performed at 1302 and 1304 may be repeated any suitable number “Y” of times, as indicated at 1306. Due to inhibitor supplied at 1302, the oxide film grows nonconformally to deposit at lower portions of the recessed feature.

Continuing, at 1308, supercycle 1301 comprises performing a passivation step. Passivation helps remove residual inhibitor from the substrate. After performing the passivation step at 1308, method 1300 may determine, at 1310, whether to perform additional supercycles 1301. If yes, method 1300 will repeat supercycle 1301. If no, method 1300 terminates. As indicated at 1312, method 1300 comprises repeating supercycle 1301 a number Z times. In contrast to method 1200 which comprises one passivation step, method 1300 comprises performing a plurality of passivation steps. Whereas method 1200 comprises one passivation step per ALD cycle comprising an inhibitor, method 1300 comprises performing a passivation step after Y ALD cycles comprising an inhibitor.

In other examples, ALD cycles, ALD cycles comprising an inhibitor, and passivation steps may be performed any suitable number of times and in any suitable order.

Thus, film growth on a substrate may be inhibited to different degrees on different surfaces based upon a concentration of inhibitor deposited to the surfaces. As such, film growth can be relatively faster at a second depth in a recessed feature compared to at a first depth, wherein the first depth is closer to an opening of the recessed feature than the second depth. This may help to form 3D circuit structures that exhibit greater reliability and/or electrical performance, and display greater resistance to breakdown. Further, a nonconformal film that is relatively thicker at a relatively greater depth within a recess can be deposited on a conformal film.

In some examples, the recessed feature formed in the substrate exhibit a high aspect ratio (HAR). A HAR feature can include features having a vertical: horizontal dimension ratio of greater than or equal to 20:1. In some examples the disclosed methods and processes are applicable to features having a HAR that is greater than or equal to 20:1 and less than or equal to 200:1.

In some examples, the first conformal film can be deposited so as to exhibit a film thickness of about 40 Angstroms to about 90 Angstroms. In more specific examples, the first conformal film thickness is about 60 Angstroms to about 70 Angstroms. The second film can be deposited in the lower portions of the recessed feature so as to exhibit a film thickness of about 5 Angstroms to about 20 Angstroms. In examples in which the recess is formed in a 3D memory structure, the second film can extend upwardly along the sides of the recessed feature to a height of ten wordlines or less.

In some embodiments, the methods and processes described herein may be tied to a computing system of one or more computing devices. In particular, such methods and processes may be implemented as a computer-application program or service, an application-programming interface (API), a library, and/or other computer-program product.

FIG. 14 schematically shows an example computing system 1400 that can enact one or more of the methods and processes described above. Computing system 1400 is shown in simplified form. Computing system 1400 may take the form of one or more personal computers, workstations, computers integrated with substrate processing tools, and/or network accessible server computers. Controller 130 is an example of computing system 1400.

Computing system 1400 includes a logic machine 1402 and a storage machine 1404. Computing system 1400 may optionally include a display subsystem 1406, input subsystem 1408, communication subsystem 1410, and/or other components not shown in FIG. 14.

Logic machine 1402 includes one or more physical devices configured to execute instructions. For example, the logic machine may be configured to execute instructions that are part of one or more applications, services, programs, routines, libraries, objects, components, data structures, or other logical constructs. Such instructions may be implemented to perform a task, implement a data type, transform the state of one or more components, achieve a technical effect, or otherwise arrive at a desired result.

The logic machine may include one or more processors configured to execute software instructions. Additionally or alternatively, the logic machine may include one or more hardware or firmware logic machines configured to execute hardware or firmware instructions. Processors of the logic machine may be single-core or multi-core, and the instructions executed thereon may be configured for sequential, parallel, and/or distributed processing. Individual components of the logic machine optionally may be distributed among two or more separate devices, which may be remotely located and/or configured for coordinated processing. Aspects of the logic machine may be virtualized and executed by remotely accessible, networked computing devices configured in a cloud-computing configuration.

Storage machine 1404 includes one or more physical devices configured to hold instructions 1412 executable by the logic machine to implement the methods and processes described herein. When such methods and processes are implemented, the state of storage machine 1404 may be transformed—e.g., to hold different data.

Storage machine 1404 may include removable and/or built-in devices. Storage machine 1404 may include optical memory (e.g., CD, DVD, HD-DVD, Blu-Ray Disc, etc.), semiconductor memory (e.g., RAM, EPROM, EEPROM, etc.), and/or magnetic memory (e.g., hard-disk drive, floppy-disk drive, tape drive, MRAM, etc.), among others. Storage machine 1404 may include volatile, nonvolatile, dynamic, static, read/write, read-only, random-access, sequential-access, location-addressable, file-addressable, and/or content-addressable device.

It will be appreciated that storage machine 1404 includes one or more physical devices. However, aspects of the instructions described herein alternatively may be propagated by a communication medium (e.g., an electromagnetic signal, an optical signal, etc.) that is not held by a physical device for a finite duration.

Aspects of logic machine 1402 and storage machine 1404 may be integrated together into one or more hardware-logic components. Such hardware-logic components may include field-programmable gate arrays (FPGAs), program- and application-specific integrated circuits (PASIC/ASICs), program- and application-specific standard products (PSSP/ASSPs), system-on-a-chip (SOC), and complex programmable logic devices (CPLDs), for example.

When included, display subsystem 1406 may be used to present a visual representation of data held by storage machine 1404. This visual representation may take the form of a graphical user interface (GUI). As the herein described methods and processes change the data held by the storage machine, and thus transform the state of the storage machine, the state of display subsystem 1406 may likewise be transformed to visually represent changes in the underlying data. Display subsystem 1406 may include one or more display devices utilizing virtually any type of technology. Such display devices may be combined with logic machine 1402 and/or storage machine 1404 in a shared enclosure, or such display devices may be peripheral display devices.

When included, input subsystem 1408 may comprise or interface with one or more user-input devices such as a keyboard, mouse, or touch screen. In some embodiments, the input subsystem may comprise or interface with selected natural user input (NUI) componentry. Such componentry may be integrated or peripheral, and the transduction and/or processing of input actions may be handled on- or off-board. Example NUI componentry may include a microphone for speech and/or voice recognition, and an infrared, color, stereoscopic, and/or depth camera for machine vision and/or gesture recognition.

When included, communication subsystem 1410 may be configured to communicatively couple computing system 1400 with one or more other computing devices. Communication subsystem 1410 may include wired and/or wireless communication devices compatible with one or more different communication protocols. As non-limiting examples, the communication subsystem may be configured for communication via a wireless telephone network, or a wired or wireless local- or wide-area network. In some embodiments, the communication subsystem may allow computing system 1400 to send and/or receive messages to and/or from other devices via a network such as the Internet.

The foregoing description is merely illustrative in nature and is in no way intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims. It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

As used herein, the phrase one or more of A, B, or C should be construed to mean a logical (A OR B OR C), using a non-exclusive logical OR, and should not be construed to mean “at least one of A, at least one of B, and at least one of C.”

The subject matter of the present disclosure includes all novel and non-obvious combinations and sub-combinations of the various processes, systems and configurations, and other features, functions, acts, and/or properties disclosed herein, as well as any and all equivalents thereof.

1. A method comprising:
arranging a substrate comprising a recessed feature on a substrate support in an atomic layer deposition (ALD) processing chamber, the substrate comprising a substrate surface, and the recessed feature comprising a recess wall extending into the substrate from an opening of the recessed feature in the substrate surface, the recess wall comprising a first depth and a second depth, wherein the first depth is closer to the opening than the second depth;
supplying an inhibitor to the ALD processing chamber and forming a plasma comprising the inhibitor in the ALD processing chamber to create an inhibited surface at the first depth; and
performing ALD to deposit a film that is thicker at the second depth than at the first depth.

2. The method of claim 1, wherein the film comprises one or more of silicon oxide, silicon oxynitride, silicon nitride, silicon carbide, or silicon oxycarbide.

3. The method of claim 2, wherein the inhibitor comprises a fluorine-containing inhibitor.

4. The method of claim 1, wherein the film comprises a metal film.

5. The method of claim 4, wherein the inhibitor comprises a nitrogen-containing inhibitor.

6. The method of claim 5, wherein the nitrogen-containing inhibitor comprises one or more of nitrogen (N₂), ammonia (NH₃), an amine, a diamine, or an aminoalcohol.

7. The method of claim 1, wherein the film comprises one or more of a metal oxide film or a laminate film the laminate film comprising metal oxide layers and silicon oxide layers.

8. The method of claim 1, further comprising removing the inhibitor from the substrate surface by a passivation cycle.

9. The method of claim 1, wherein the recessed feature comprises an aspect ratio that is greater than or equal to 20:1, and less than or equal to 200:1.

10. The method of claim 1, further comprising performing ALD to deposit a conformal film on the substrate including within the recessed feature prior to supplying the inhibitor to the processing chamber

11. The method of claim 10, wherein the conformal film and the film that is thicker at the second depth comprise a same material.

12. The method of claim 11, wherein the conformal film comprises a thickness of about 40 to about 90 Angstroms.

13. The method of claim 1, wherein the inhibitor and a film precursor are supplied to the ALD processing chamber simultaneously.

14. A method comprising:
arranging a substrate comprising a recessed feature on a substrate support in an atomic layer deposition (ALD) processing chamber, the substrate comprising a substrate surface, the recessed feature comprising a recess wall extending into the substrate from an opening of the recessed feature, the recessed feature further comprising a first depth and a second depth, the first depth being closer to the opening than the second depth;
performing ALD to deposit a first conformal film on the substrate including on the recess wall;
supplying an inhibitor to the processing chamber and forming a plasma comprising the inhibitor in the processing chamber to create an inhibited surface within the recessed feature at the first depth; and
performing ALD to deposit a second film that is thicker at the second depth than at the first depth.

15. The method of claim 14, wherein the first conformal film and the second film independently comprise one or more of silicon oxide, silicon oxynitride, silicon nitride, silicon carbide, or silicon oxycarbide.

16. The method of claim 14, wherein the inhibitor comprises a fluorine-containing inhibitor.

17. The method of claim 15 wherein at least one of the conformal film and the second film comprises a metal film.

18. The method of claim 17, wherein the inhibitor comprises a nitrogen-containing inhibitor.

19. A structure formed on a substrate by atomic layer deposition (ALD) comprising:
a recessed feature formed on the substrate, the recessed feature comprising a recess wall extending into the substrate from an opening of the recessed feature in a substrate surface, the recess wall comprising a first depth and a second depth, wherein the first depth is closer to the opening than the second depth;
a first conformal film disposed on the substrate surface and on the recess wall; and
a second film disposed on the first conformal film at the second depth and not at the first depth such that an overall film thickness is thicker at the second depth than at the first depth.

20. The structure of claim 19, wherein the first conformal film and the second film independently comprise silicon oxide, silicon oxynitride, silicon nitride, silicon carbide, or silicon oxycarbide.
